(19) United States
(12) Patent Application Publication
(10) Pub. No.: US 2009/0109366 A1
(43) Pub. Date: Apr. 30, 2009

(54) Liquid Crystal Display Without Bezel

(76) Inventor: Barret Lippey, Belmont, MA (US)

Correspondence Address: Bose Corporation;c/o Donna Griffiths, The Mountain, MS 40, IP Legal - Patent Support, Framingham, MA, 01701, US

(21) Appl. No.: 11/927,378

(22) Filed: Oct. 29, 2007

(51) Int. Cl. G02F 1/1335; G02F 1/1333; H01J 1/54; G02B 5/00; H05K 5/00

(52) U.S. Cl. 349/58; 349/84; 313/582; 359/601

(57) ABSTRACT

A bezel-less video display that includes a liquid-crystal display panel, a sheet in front of the liquid-crystal display panel, and an optically transparent material which fills the volume between the display panel and the sheet. The sheet has an antiglare coating which has a gloss level less than 50 gloss units at 60 degrees angle of incidence. The antiglare coating also has a transmissive resolution of at least 10 cycles/mm.

### BACKGROUND OF THE INVENTION

Liquid crystal displays (LCDs) are used to present video or other image information to a viewer. Conventional LCDs have a bezel that covers the frame region of the front of the display.

### SUMMARY OF THE INVENTION

In general, in one aspect, a video display including a liquid-crystal display panel, a sheet having a first surface facing the liquid-crystal display panel and a second surface opposite the first surface, the second surface facing away from the liquid-crystal display panel, the sheet covering the liquid-crystal display panel, an optically transparent material which substantially fills a volume between an image forming area of the liquid-crystal panel and the sheet; and a first antiglare coating on the second surface of the sheet; wherein the antiglare coating has a gloss less than about 50 gloss units at about 60 degrees angle of incidence and a transmissive resolution of at least about 10 cycles/mm.

Implementations may include one or more of the following features. The optically transparent material may be an adhesive bonding material that adhesively bonds the image forming area to the first surface of the sheet. The adhesive bonding material may be a silicone bonding material. The distance between the first surface of the sheet and the front surface of the liquid-crystal display panel facing the first surface of the sheet may be greater than 1 mm. The sheet may extend over the frame of the liquid-crystal panel to form a flat front surface for the video display. The sheet may visibly hide the frame of the liquid-crystal panel. The frame region of the sheet may be coated with a substantially opaque layer to block the reflection of the frame of the liquid-crystal panel through the sheet. The opaque layer may be the same color as the liquid-crystal display in the off state. The opaque layer may be made from black paint. The video display may be bezel-less. The sheet may be made from a glass or plastic material. The plastic material may be polycarbonate or r acrylic. The first antiglare coating may have a gloss between 20 and 40 gloss units at 60 degrees angle of incidence. The liquid-crystal display panel may have a second antiglare coating located at the front surface of the liquid-crystal display panel which faces the sheet. The optically transparent material may be chosen so that the index of refraction of the optically transparent material matches the index of refraction of the second antiglare coating within about 0.1. The optically transparent material may be chosen so that the index of refraction of the optically transparent material matches the index of refraction of the second antiglare coating within about 0.05. The liquid-crystal display panel may have an image forming area with a diagonal size greater than 40 inches.

In general, in one aspect, a video display including a plasma display panel, a sheet having a first surface facing the plasma display panel and a second surface opposite the first surface, the second surface facing away from the liquid-crystal display panel, an adhesive bonding material that secures the plasma display panel to the first surface of the sheet; and an antiglare coating on the second surface of the sheet, wherein the antiglare coating has a gloss less than 50 gloss units at 60 degrees angle of incidence and a transmissive resolution of at least 10 cycles/mm.

In general, in one aspect, a method of hiding the frame of a liquid-crystal display panel that includes adhesively bonding a sheet to the front of the liquid-crystal display panel with an adhesive bonding material, wherein the adhesive bonding material fills the volume between the liquid-crystal display panel and the sheet. The sheet is configured to block the reflection of the frame through the sheet while allowing the light from the liquid-crystal display panel to pass through the sheet. The sheet also includes an antiglare coating with a gloss less than 50 gloss units at 60 degrees angle of incidence and a transmissive resolution of at least 10 cycles/mm.

Implementations may include the following feature. The distance between the sheet and the front surface of the liquid-crystal display panel facing the first surface of the sheet may be greater than 1 mm.

In general, in one aspect, a method of improving the contrast of a liquid-crystal display panel which includes adhesively bonding a sheet in front of the liquid-crystal display panel with an adhesive bonding material, wherein the adhesive bonding material fills the volume between the liquid-crystal display panel and the sheet. The adhesive bonding material has an index of refraction that matches the front surface of the liquid-crystal display which faces the sheet within 0.1. The sheet has an antiglare coating with a gloss less than 50 gloss units at 60 degrees angle of incidence and a transmissive resolution of at least 10 cycles/mm.

### BRIEF DESCRIPTION OF THE SEVERAL VIEWS OF THE DRAWING

FIG. 1 is a perspective view of an LCD panel with a bezel;

FIG. 2 is a side sectional view of an LCD panel without a bezel;

FIG. 3 is a front view of an LCD panel without a bezel.

FIG. 4 is a side view of a gloss measurement configuration.

### DETAILED DESCRIPTION

A display is a complete image producing system including electronics and packaging. A flat panel is an image producing subsystem that consists only of the optical (and directly associated electrical and mechanical parts) necessary to produce the image. Flat panel video displays may be based on various flat panel technologies such as plasma display panels (PDP), organic light emitting diode (OLED) panels, or LCD panels. When LCD panels are used, the component parts of the LCD panel are generally held together by a metal frame. Since this metal frame covers a portion of the edge (or frame region) of the front of the panel, and since it protrudes forward (towards the viewer) from the front of the panel, conventional LCDs use a bezel that is generally placed over the frame to hide the frame from the viewer. The bezel may be made of plastic or other materials. The diagonal size of the image forming area of the display may be 1 to 60 inches or more. Displays with a diagonal size greater than 40 inches are suitable for viewing from various positions throughout a typically-sized household living room, or many other consumer indoor environments.

Flat panel video displays use two fundamentally different types of front surface treatments to help reduce visible reflections from the outside environment. One type is called AR (antireflection). An AR treatment is usually an interference coating on the front of the display that cancels out some of the reflected light so that the viewer sees less glare. The other common type of front surface treatment is called antiglare (AG). An AG treatment is usually a diffusing coating or a roughened surface that causes the reflected light to be diffused over a wide viewing angle. Combination AR/AG coatings are also available that both reduce the reflection and diffuse the reflection. The front surface treatment of an LCD panel is typically an AG coating, although some LCD panels have an AR coating instead.

Front surface treatments may be characterized by their gloss and their transmissive resolution. Gloss is the amount of reflection at a predetermined angle which is normalized using a known reference sample. Transmissive resolution is a measure of the ability to optically transmit an image without degrading the visible spatial resolution. Test methods for both of these properties are discussed below.

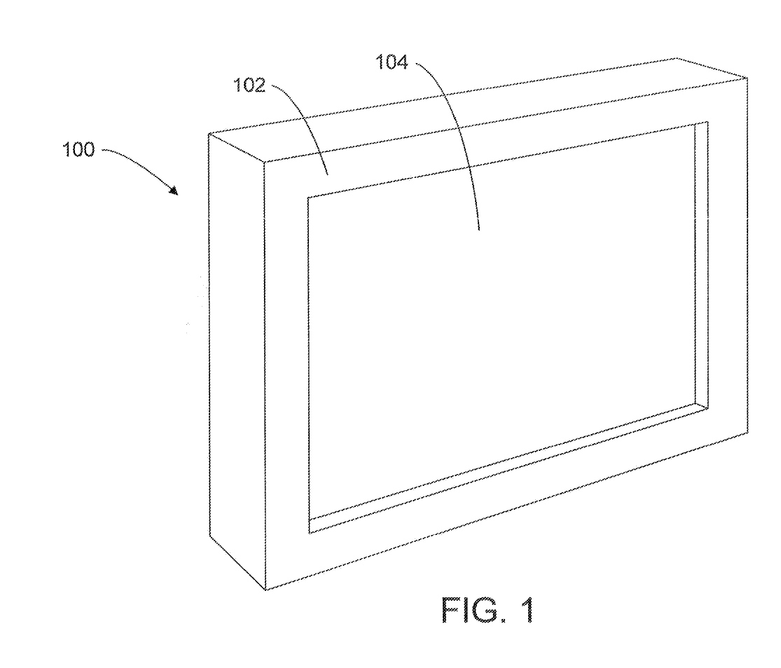

FIG. 1 shows a perspective view of an LCD 100 with a bezel 102. The bezel protrudes forward (towards the viewer) from the plane of an image forming area of the flat panel 104.

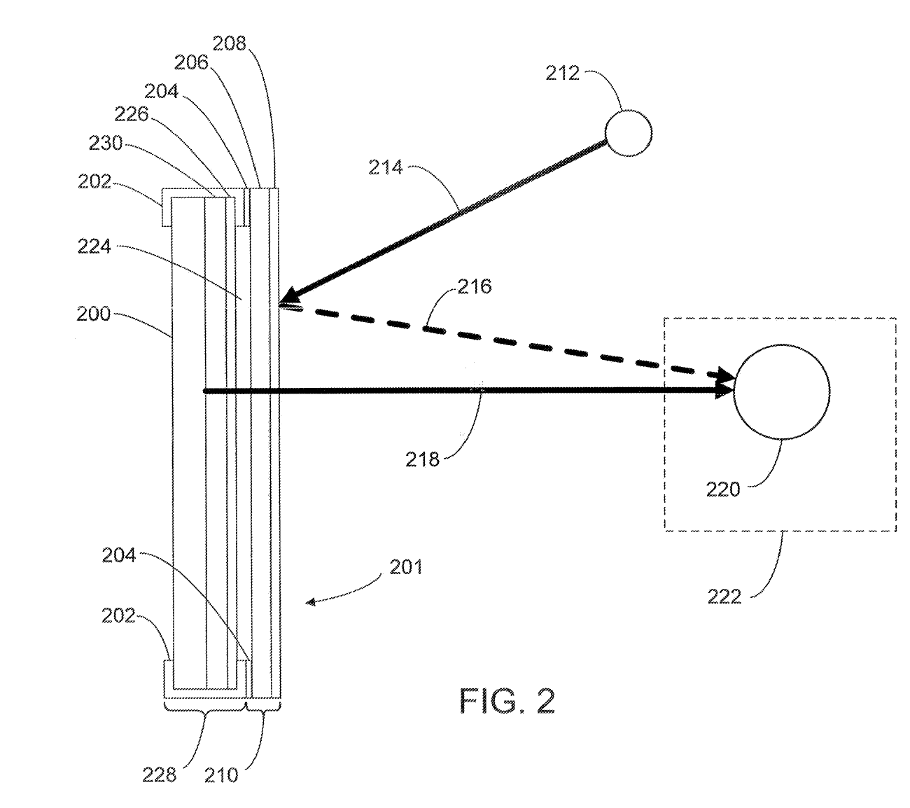

FIG. 2 shows a side sectional view of a bezel-less display 201. An LCD flat panel 228 includes a back light unit 200, an LCD light valve 230, an optional LCD-panel AG coating 226, and a frame 202. A front sheet 210 includes a blocking layer 204, a structural support 206, and a front AG coating 208. The front sheet 210 is attached to the LCD flat panel 228 with an adhesive 224 which preferably fills the entire visible space between the structural support 206 and the LCD optional LCD panel AG coating 226. If there is no optional LCD-panel AG coating 226, the front sheet 210 is attached to the LCD flat panel 228 with an adhesive 224 which preferably fills the entire visible space between the structural support 206 and the LCD light valve 230. Image forming light 218 is emitted from the back light unit 200, passes through the LCD light valve 230 to form an image, and passes through the optional LCD panel AG coating 226, the adhesive 224, the structural support 206, the front AG coating 208, and reaches a viewer 220 in a viewing zone 222. An ambient light source 212 produces ambient light 214 which reflects primarily from the front AG coating 208 and forms reflected light 216 which reaches the viewer 220.

In FIG. 2, the frame 202 mechanically holds together and supports the back light unit 200 and the LCD light valve 230 as well as optional LCD panel AG coating 226. The blocking layer 204 hides the frame 202 so that the frame 202 is not visible to the viewer 220. The optional AG coating 226 is deposited directly on the LCD light valve 230. Instead of the optional AG coating 226, there may be an AR coating, or there may be no coating. The structural support 206 may be made of polycarbonate, acrylic, or other optically transparent plastic or optically transparent glass. Structural support 206 may be tinted with a neutral density gray color or any desired color.

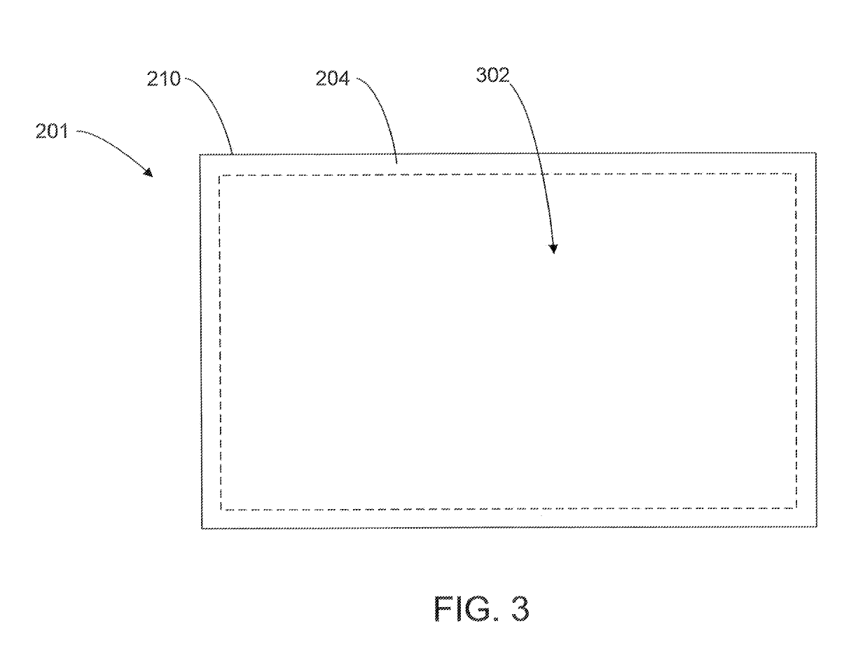

FIG. 3 shows a front view of the bezel-less display 201. The front sheet 210 is seen on the front of the bezel-less display 201. It forms a flat and smooth front surface across the front of the bezel-less display 201 so that there are no protrusions or depressions on the front of the display. In the off state of the bezel-less display 201, the front of the bezel-less display 201 preferably has a uniform, black appearance and the appearance of blocking layer 204 matches the appearance of an image forming area 302. The matching may be achieved by using a black or close-to-black paint for blocking layer 204. The paint color of the blocking layer 204 may match the color of the image forming area 302 when image forming area 302 is in the off state. Alternatively, the color of blocking layer 204 may be selected to fulfill other aesthetic purposes. Blocking layer 204 forms a frame region around the front of the display. The frame region extends across an area of the front of the display near the edge of the display, and extends over a small area compared to the entire image area of the display.

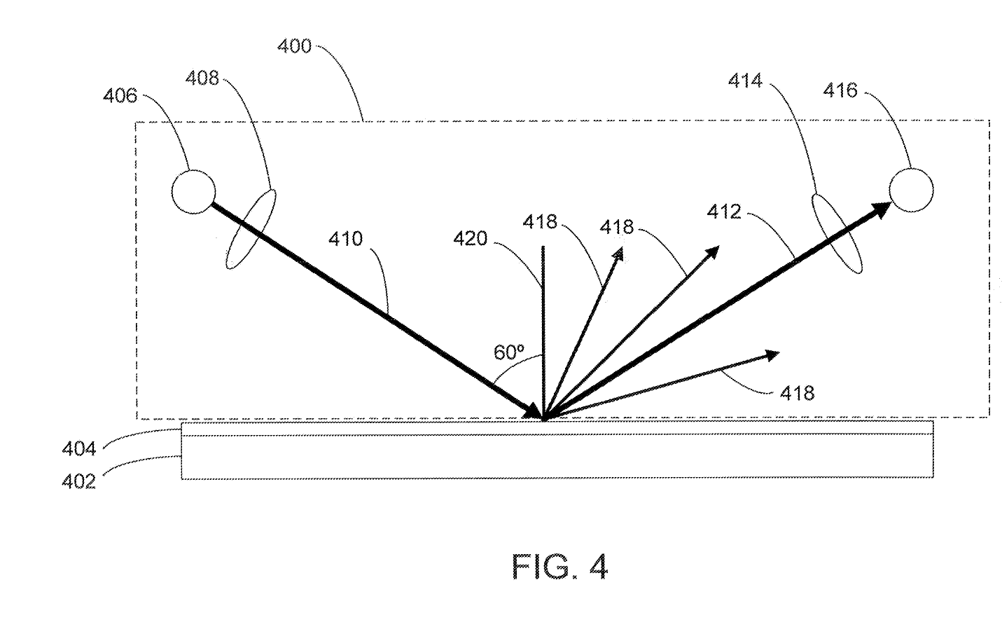

FIG. 4 shows the configuration used for measuring gloss. A gloss measurement apparatus 400 is used to measure the gloss of a structural member 402 with a coating 404. The gloss measurement apparatus 400 consists of a light source 406, an incident light beam 410, a lens 408, a specularly reflected light beam 412, a lens 414, and a light detector 416. During the measurement, the incident light beam 410 is reflected from the coating 404 to form the specularly reflected light beam 412 and diffusely reflected light beams 418. Detector 416 only counts the specularly reflected light beam 412 and does not count the diffusely reflected light beams 418. The angle of incidence is the angle between the incident light beam 410 and a perpendicular 420. The angle of specular reflection is the angle between the specularly reflected light beam 412 and the perpendicular 420. The angle of incidence equals the angle of specular reflection. Gloss measurement apparatus 400 uses electronic circuitry to calibrate with a black glass reference sample mounted in the position of coating 404 and structural member 402. The black glass reference sample typically has a gloss level of about 94 gloss units at 60 degrees angle of incidence. A high gloss level corresponds to a specularly reflecting (shiny) surface and a low gloss level corresponds to a diffusely reflecting (matte) surface.

Transmissive resolution is measured using the test method of FAA-E-2481a, section 3.8.4.1. In this method, a viewer with normal, or corrected to normal, vision observes a standard resolution test pattern through the coating under test. The transmissive resolution is determined by the highest resolution pattern that can be seen with distinguishable bars. The units of transmissive resolution are cycles/mm (which is equivalent to line pairs/mm).

The adhesive 224 may be a silicone adhesive, UV-cure adhesive, or other optically transparent adhesive. Stress on the LCD panel may affect the operation of the liquid crystal, so it is beneficial to use an adhesive that has low shrinkage and that cures to a soft state to reduce the possibility of stress. Silicone adhesive that cures to a Shore A hardness of about 30 may be used for adhesive 224. The index of refraction of the adhesive 224 determines the index match of the front sheet 210 to the LCD flat panel 228. Good index of refraction matching is desirable to reduce the reflection of ambient light at the interfaces between the adhesive 224, the front sheet 210, and the LCD flat panel 228. The index of refraction of the adhesive 224 may be in the range of 1.4 to 1.6. The index matching of the adhesive to the front of the display panel should be within about 0.1 to achieve a low reflection from the interface. To reduce the reflection even further, an index matching of 0.05 is desirable.

To reduce visible glare from the front of the display, the front surface of the sheet may be coated with an antiglare coating that has a gloss level of less than about 50 gloss units. To maintain low glare and also maximum transmissive resolution, the coatings may have a gloss level of between 20 and 40 gloss units along with a transmissive resolution of greater than 10 cycles/mm. Examples of coatings that have gloss of less than 50 gloss units and transmissive resolution greater than 10 cycles/mm can be found in the Duravue 2000 series of coatings from TSP Incorporated in Batavia, Ohio. One example is the Duravue 2000 34 gloss coating which has a transmissive resolution of 13 cycles/mm when measured according to the test method of FAA-E-2481a, section 3.8.4.1. Note that the published information from TSP Incorporated uses a test method that gives a different transmissive resolution result than FAA-E-2481a, section 3.8.4.1.

One benefit of a bezel-less LCD such as that shown in FIG. 2 is as a design element. The appearance of the bezel-less LCD is smooth and simple compared to the appearance of an LCD with a bezel. The bezel-less design is more appropriate for a high-end LCD that looks distinctively different than conventional LCDs with bezels.

An unexpected benefit of the bezel-less design of FIG. 2 is that contrast in the presence of ambient light may be increased relative to the contrast of an existing LCD panel alone. Contrast is defined as the intensity of the brightest possible image on the screen divided by the intensity of the dimmest possible image on the screen. An improvement in contrast may be obtained if the AG coating on the front of the sheet 208 has different diffusing properties than the AG coating on the front of the LCD panel 226. Through adhesive wetting of the coating on the front of the panel using the adhesive 224, the diffusion of coating 226 is completely or mostly removed. The front sheet 210 may be completely clear (no significant absorption) or may have a tint (with significant absorption). When front sheet 210 has a tint, the visible contrast may be improved further beyond the contrast improvement that occurs by replacing the coating 226 with a coating like coating 208.

Other implementations are also within the scope of the following claims.

What is claimed is:

1. A video display comprising:
a liquid-crystal display panel;
a sheet having a first surface facing the liquid-crystal display panel and a second surface opposite the first surface, the second surface facing away from the liquid-crystal display panel, the sheet covering the liquid-crystal display panel;
an optically transparent material which substantially fills a volume between an image forming area of the liquid-crystal panel and the sheet; and
a first antiglare coating on the second surface of the sheet;
wherein the antiglare coating has a gloss less than about 50 gloss units at about 60 degrees angle of incidence and a transmissive resolution of at least about 10 cycles/mm.

2. A video display in accordance with claim 1, wherein the optically transparent material is an adhesive bonding material that adhesively bonds the image forming area to the first surface of the sheet.

3. A video display in accordance with claim 2, wherein the adhesive bonding material comprises a silicone bonding material.

4. A video display in accordance with claim 1, wherein a distance between the first surface of the sheet and a front surface of the liquid-crystal display panel facing the first surface of the sheet is greater than 1 mm

5. A video display in accordance with claim 1, wherein the sheet extends over a frame of the liquid-crystal panel to form a flat front surface for the video display.

6. A video display in accordance with claim 5, wherein the sheet visibly hides the frame of the liquid-crystal panel.

7. A video display in accordance with claim 6, wherein the frame region of the sheet is coated with a substantially opaque layer to block a reflection of the frame of the liquid-crystal panel through the sheet.

8. A video display in accordance with claim 7, wherein the layer is substantially the same color as the liquid-crystal display in an off state.

9. A video display in accordance with claim 7, wherein the layer comprises black paint.

10. A video display in accordance with claim 1, wherein the video display is bezel-less.

11. A video display in accordance with claim 1, wherein the sheet comprises a glass material.

12. A video display in accordance with claim 1, wherein the sheet comprises a plastic material.

13. A video display in accordance with claim 12, wherein the plastic material comprises polycarbonate.

14. A video display in accordance with claim 13, wherein the plastic material comprises acrylic.

15. A video display in accordance with claim 1, wherein the first antiglare coating has a gloss between about 20 and about 40 gloss units at about 60 degrees angle of incidence.

16. A video display in accordance with claim 1, wherein the liquid-crystal display panel comprises a second antiglare coating located at a front surface of the liquid-crystal display panel which faces the sheet.

17. A video display in accordance with claim 16, wherein the optically transparent material is chosen so that an index of refraction of the optically transparent material matches an index of refraction of the second antiglare coating within about 0.1.

18. A video display in accordance with claim 16, wherein the optically transparent material is chosen so that an index of refraction of the optically transparent material matches an index of refraction of the second antiglare coating within about 0.05.

19. A video display in accordance with claim 1, wherein the liquid-crystal display panel has an image forming area with a diagonal size greater than 40 inches.

20. A video display comprising:
a plasma display panel;
a sheet having a first surface facing the plasma display panel and a second surface opposite the first surface, the second surface facing away from the liquid-crystal display panel;
an adhesive bonding material that secures the plasma display panel to the first surface of the sheet; and
an antiglare coating on the second surface of the sheet;
wherein the antiglare coating has a gloss less than about 50 gloss units at about 60 degrees angle of incidence and a transmissive resolution of at least about 10 cycles/mm.

21. A method of hiding a frame of a liquid-crystal display panel comprising:
adhesively bonding a sheet to a front of the liquid-crystal display panel with an adhesive bonding material, wherein the adhesive bonding material fills a volume between the liquid-crystal display panel and the sheet, the sheet being configured to block a reflection of the frame through the sheet while allowing a light from the liquid-crystal display panel to pass through the sheet, the sheet comprising an antiglare coating with a gloss less than about 50 gloss units at about 60 degrees angle of incidence and a transmissive resolution of at least about 10 cycles/mm.

22. A method in accordance with claim 21, wherein a distance between the sheet and a front surface of the liquid-crystal display panel facing the first surface of the sheet is greater than 1 mm.

23. A method of improving the contrast of a liquid-crystal display panel, comprising:
adhesively bonding a sheet in front of the liquid-crystal display panel with an adhesive bonding material, wherein the adhesive bonding material fills substantially a volume between the liquid-crystal display panel and the sheet, the adhesive bonding material matching an index of refraction of a front surface of the liquid-crystal display which faces the sheet within about 0.1, the sheet comprising an antiglare coating with a gloss less than about 50 gloss units at about 60 degrees angle of incidence and a transmissive resolution of at least about 10 cycles/mm.
